(19) United States
(12) Patent Application Publication
(10) Pub. No.: US 2026/0150312 A1
(43) Pub. Date: May 28, 2026

(54) Diode made of ice

(71) Applicant: Stanislav Vadimovich Yefimov, St. Peterburg (RU)

(72) Inventor: Stanislav Vadimovich Yefimov, St. Peterburg (RU)

(21) Appl. No.: 18/957,968

(22) Filed: Nov. 25, 2024

(51) Int. Cl. H01L 29/862; H01L 29/66

(52) U.S. Cl. CPC H10D 8/30; H10D 99/00

(57) ABSTRACT

Ice is a new semiconductor material. Ice doping is accomplished by preparing aqueous solutions of acids (donor impurity) and aqueous solutions of bases (acceptor impurity) followed by freezing the solutions. A semiconductor device, namely a diode, is made by tightly joining or fusing a piece of acid-doped ice and a piece of base-doped ice.

### BACKGROUND

The first semiconductor materials and devices were invented more than 100 years ago. 1874: Semiconductor Point-Contact Rectifier Effect was Discovered by Ferdinand Braun when he probed a galena crystal (lead sulfide) with the point of a thin metal wire, Braun noted that current flowed freely in one direction only. Around 1904, Henry Harrison Chase Dunwoody developed a cat's-whisker detector using carborundum, and Greenleaf Whittier Pickard developed a cat's-whisker detector using galena. The first silicon point-contact crystal detector was invented in 1906 by Greenleaf Whittier Pickard. In 1940, Russell Ohl learned about the photovoltaic effects in silicon and the p-n junction. Russell Ohl, who, in 1940 stumbled on the semiconductor “p-n” junction. Russell Ollier's invention is the closest to the invention presented here. Russell Ollier's patent U.S. Pat. No. 2,402,662 for LIGHT-SENSITIVE ELECTRIC DEVICE may be considered to some extent as a prototype of this invention. The effect of one-way conductivity of the contact of an aqueous solution of acid and an aqueous solution of base has been known for a long time. This effect was described in 1973 by Z. Noszticzius and A. Schubert and in their work: “Electrolyte-Diode . . . ”. However, it is difficult to practically use this effect for two main reasons: 1. Electrolysis of solutions with a change in the chemical composition of the solutions. 2. Instability of the acid-base contact through a membrane, gel, or thin capillary. In this invention, we do not have the problem with electrolysis and contact instability by using doped ice.

### SUMMARY

The object of the invention is to create a new semiconductor material namely Ice, and a semiconductor device based on it. The present invention relates to the solid semiconductor composition comprising: a frozen aqueous solution of an acid and a frozen aqueous solution of a base. An inert electrode is frozen into each of the solutions. Both frozen solutions are tightly connected to each other, forming a contact surface. The semiconductor device is a structure consisting of two pieces of doped ice and electric wires connected to the frozen into the ice electrodes.

### BRIEF DESCRIPTION OF DRAWINGS.

FIG. 1. Plastic cups filled with aqueous acid and aqueous base solutions. The solutions are frozen in a freezer.

FIG. 2. The bottoms of plastic cups show electrical wires (electrodes) frozen into the ice.

FIG. 3. The installation is assembled. Two pieces of ice are tightly pressed together. Electrical wires are connected to the multimeter.

FIG. 4. Scheme of the setup for recording the semiconductor properties of the contact of the acid-doped ice (A) and the base-doped ice (B). S—switch. M—multimeter.

FIG. 5 Table 1. Resistance measurement mode, doping concentration in ice 0.1 M and 0.001 M, temperature 0° C.

FIG. 6 Table 2. Diode test mode, doping concentration in ice 0.1 M, temperature 0° C. The voltage drop on the diode was measured.

FIG. 7. Figure explaining the operation of an ice diode. In the figure: −e are the main carriers of electric charge in acid-doped ice, +e are the main carriers of electric charge in base-doped ice. At a given polarity of the applied electric potential, the diode is “closed”. The diode is “open” when the polarity is reversed, as in the diode symbol at the bottom of the figure.

### DETAILED DESCRIPTION

The invention will now be described more in detail having reference to the accompanying drawings.

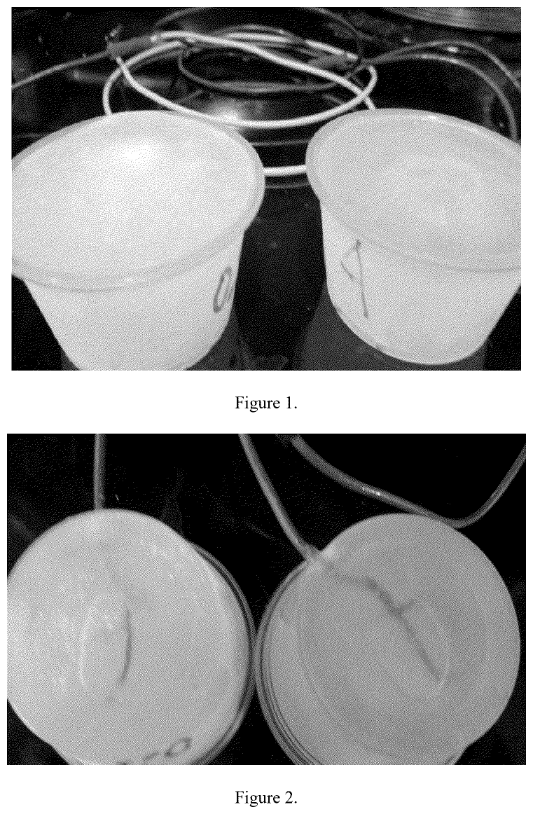

A new semiconductor material is ice made from frozen aqueous solutions of acids and bases (FIG. 1).

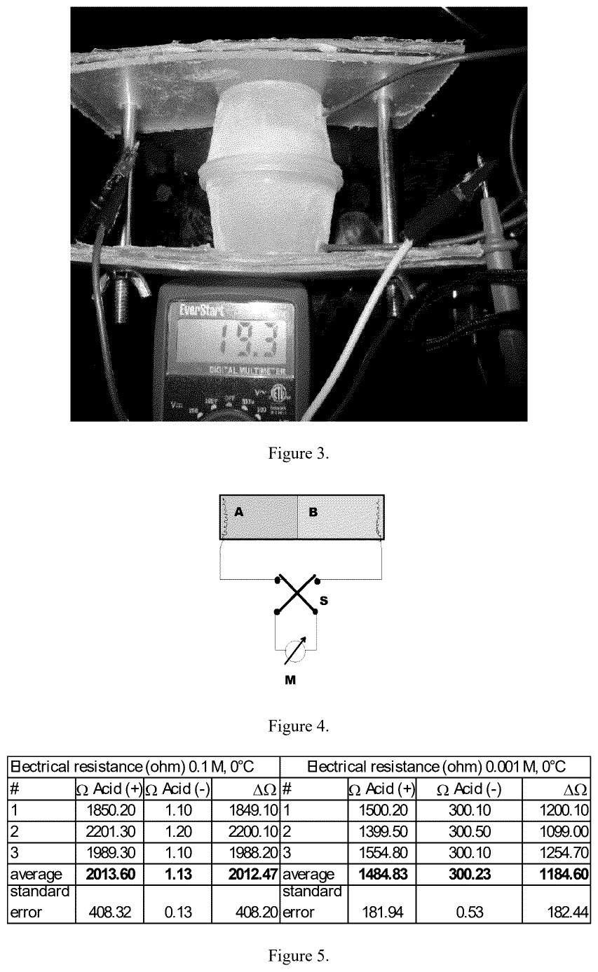

Semiconductor device—diode. A diode is a device that provides contact between a frozen aqueous solution of acid and a frozen aqueous solution of base and allows electric current to pass through this contact with low resistance in the forward direction and with high resistance in the reverse direction (FIG. 3, FIG. 4).

Electric wires are frozen into each of the solutions (FIG. 2). Electrical wires are connected to the multimeter (FIG. 3).

The setup scheme for recording the semiconductor properties of the contact of frozen aqueous solutions of acid and base is presented in FIG. 4.

The material, which has proved very satisfactory, is of high purity. The water should be distilled, double-distilled, or deionized and vacuumed immediately before the solution is prepared to remove traces of dissolved gases. Good results are achieved when the solutions are prepared in an inert gas atmosphere, and the solutions are frozen in a vacuum desiccator filled with inert gas. Acids and bases must be of the highest grade—analytical grade or higher.

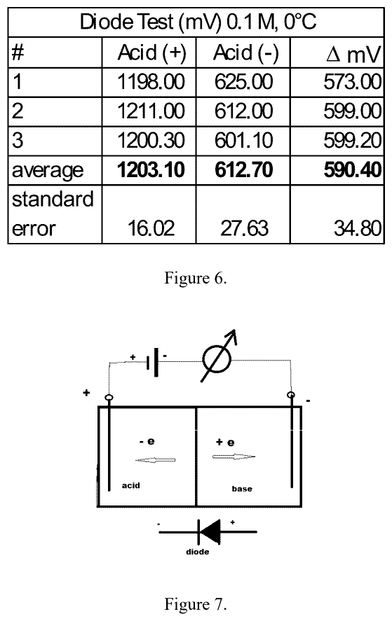

The data confirming the operability of the patented diode were obtained using a universal multimeter. The measurements were taken in resistance measurement mode (FIG. 5) and in diode test mode (FIG. 6). In resistance measurement mode, the measurement accuracy is ∓(1.2%+5). The maximum open circuit voltage is 1 V. In diode test mode, the approximate forward voltage drop of the diode was measured. The open circuit voltage is about 2.2 V. The measurements were carried out in pairs changing the polarity from (+/−) to (−/ +). Each series had 3 pairs of measurements. The difference in the values in the pair (ΔΩand Δmv), the average value of each polarity, and the average value of the difference were calculated. The standard error of the mean was calculated at a confidence level of 95%. In the first series of experiments, the resistance of tightly connected pieces of acid-doped ice and base-doped ice was measured in the direction perpendicular to the contact surface. The polarity of the electrodes was changed in pairs. FIG. 5 presents the measurement results for two concentrations of the ligating agent (acid and base). The left column (Ω Acid (+)) shows the resistance of the device when a positive potential is applied to the electrode frozen into acid-doped ice, and the right column (Ω Acid (−)) of the opposite polarity. The predominantly one-sided conductivity is obvious. FIG. 6 presents the measurement results for 0.1 M concentration of the ligating agent (acid and base) at 0° C. The predominantly one-sided conductivity is obvious.

From these two tables it is clearly seen that the conductivity in the direction from the base-doped ice to the acid-doped ice is significantly greater than in the opposite direction. FIG. 7 shows the interpretation of the obtained data: Doping ice with acid creates n-type conductivity of the semiconductor, and doping ice with a base creates p-type conductivity of the semiconductor. An n-p junction is created in the contact.

What is claimed is:

1. A method for producing a solid semiconductor material (ice) and a semiconductor device (diode) based on it, comprising preparing two aqueous solutions: 1) of the acid with a concentration of no more than 0.5 mole by dissolving an aliquot of pure acid in pure water (1st) and, 2) the aqueous solution of the base with a concentration of no more than 0.5 mole by dissolving an aliquot of a pure base solution in pure water (2nd);
Electrodes connected to wires are placed into the prepared solutions;
The solutions are frozen until ice is formed together with the electrodes placed into them;
A semiconductor device, namely a diode, is assembled by tightly joining two pieces of ice doped with an acid (1st) and a piece of ice doped with a base (2nd) to form a contact surface.

2. The method and device of claim 1, where the prepared solutions of non-volatile acids and non-volatile bases are kept in a vacuum (pressure <10 mm Hg) for a time sufficient to remove dissolved gases from the solutions before freezing.

3. The method and device of claim 1, where the preparation and freezing of solutions of acids and bases are carried out in an inert gas atmosphere.

4. The method and device of claim 1, where the tight contact between the acid-doped ice block and the base-doped ice block is initially achieved using a screw, spring, or other type of clamps at low temperature, and then the temperature is slowly raised until the ice begins to melt at the point of contact; After reaching the melting point, the tightly connected ice blocks are cooled again below the melting point; In this way, the two ice blocks are “welded” together, after which the need for mechanical clamps disappears.
